(19) United States
(12) Patent Application Publication
(10) Pub. No.: US 2023/0354720 A1
(43) Pub. Date: Nov. 2, 2023

(54) METHOD OF PATTERNING A LAYER OF SUPERCONDUCTOR MATERIAL

(71) Applicant: Microsoft Technology Licensing, LLC, Redmond, WA (US)

(72) Inventors: Asbjørn Cennet Cliff DRACHMANN, Copenhagen (DK); Karl PETERSSON, Copenhagen (DK)

(73) Assignee: Microsoft Technology Licensing, LLC, Redmond, WA (US)

(21) Appl. No.: 18/044,780

(22) PCT Filed: Nov. 11, 2020
(86) PCT No.: PCT/EP2020/081723

§ 371 Date: Mar. 9, 2023

(30) Foreign Application Priority Data
Sep. 11, 2020 (GB) 2014347.5

(51) Int. Cl. H10N 60/10; C25D 11/26; C25D 11/02; C25D 11/10; C23C 14/24; C23C 14/04; C23C 14/16; H10N 60/85

(52) U.S. Cl. CPC H10N 60/10; C25D 11/26; C25D 11/022; C25D 11/10; C23C 14/24; C23C 14/042; C23C 14/16; H10N 60/85

(57) ABSTRACT

A method of patterning a layer of superconductor material comprises: forming a mask over the layer of superconductor material, the mask having at least one opening; depositing a layer of anodizable metal in the at least one opening, over a portion of the layer of superconductor material; removing the mask; and performing anodic oxidation, whereby the layer of anodizable metal protects the portion of the layer of the superconductor material from the anodic oxidation. The superconductor material is aluminium. The method allows for patterning of the superconductor material without the use of a chemical etch. This may in turn allow for improvements in resolution, and/or may avoid damage to further components or interfaces between components which may be present during the patterning. Also provided are the use of a titanium layer to protect an aluminium layer from anodic oxidation, and a semiconductor-superconductor hybrid device obtainable by the method.

### BACKGROUND

Topological quantum computing is based on the phenomenon whereby non-abelian anyons, in the form of “Majorana zero modes” (MZMs), can be formed in regions where a semiconductor is coupled to a superconductor. A non-abelian anyon is a type of quasiparticle, meaning not a particle per se, but an excitation in an electron liquid that behaves at least partially like a particle. An MZM is a particular bound state of such quasiparticles. Under certain conditions, these states can be formed close to the semiconductor-superconductor interface in a nanowire formed from a length of semiconductor coated with a superconductor. When MZMs are induced in the nanowire, it is said to be in the “topological regime”. To induce this requires a magnetic field, conventionally applied externally, and also cooling of the nanowire to, or below, a temperature that induces superconducting behaviour in the superconductor material. It may also involve gating a part of the nanowire with an electrostatic potential.

By forming a network of such nanowires and inducing the topological regime in parts of the network, it is possible to create a quantum bit (qubit) which can be manipulated for the purpose of quantum computing. A qubit is an element upon which a measurement with two possible outcomes can be performed, but which at any given time (when not being measured) can in fact be in a quantum superposition of the two states corresponding to the different outcomes.

To induce MZMs, the device is cooled to a temperature where the superconductor (e.g. aluminium, Al) exhibits superconducting behaviour. The superconductor causes a proximity effect in the adjacent semiconductor, whereby a region of the semiconductor near the interface with the superconductor also exhibits superconducting properties. Topological phase behaviour is induced in the adjacent semiconductor as well as the superconductor. It is in this region of the semiconductor where the MZMs are formed.

Another condition for inducing the topological phase where MZMs can form is the application of a magnetic field in order to lift the spin degeneracy in the semiconductor. Degeneracy in the context of a quantum system refers to the case where different quantum states have the same energy level. Lifting the degeneracy means causing such states to adopt different energy levels. Spin degeneracy refers to the case where different spin states have the same energy level. Spin degeneracy can be lifted by means of a magnetic field, causing an energy level spilt between the differently spin-polarized electrons. This is known as the Zeeman effect. The g-factor refers to the coefficient between the applied magnetic field and the spin splitting. Typically, the magnetic field is applied by an external electromagnet.

An alternative route to creating topological materials and superconducting memory elements that does not require external magnetic (Zeeman) field involves combinations of semiconducting, superconducting, and ferromagnetic insulator materials hybridized into a single device. These systems have been proposed theoretically [Sau, et al., PRL 104, 040502 (2010)].

U.S. Ser. No. 16/246,287 has also disclosed a heterostructure in which a layer of a ferromagnetic insulator is disposed between the superconductor and semiconductor in order to internally apply the magnetic field for lifting the spin degeneracy, without the need for an external magnet. U.S. Ser. No. 16/246,287 indicates that an exchange field between the ferromagnetic insulator and the semiconductor causes a split in energy levels. Examples given for the ferromagnetic insulator included compounds of heavy elements in the form of EuS, EuO, GdN, Y₃Fe₅O₁₂, Bi₃Fe₅O₁₂, YFeO₃, Fe₂O₃, Fe₃O₄, Sr₂CrReO₆, CrBr₃/CrI₃, YTiO₃ (the heavy elements being Europium, Gadolinium, Yttrium, Iron, Strontium and Rhenium).

The fabrication of nanowire heterostructures comprising InAs and Al layers has been reported [Krogstrup, et al., Nat. Mater. 14, 400 (2015)].

### SUMMARY

One aspect provides a method of patterning a layer of superconductor material, which method comprises: forming a mask over the layer of superconductor material, the mask having at least one opening; depositing a layer of anodizable metal in the at least one opening, over a portion of the layer of superconductor material; removing the mask; and performing anodic oxidation, whereby the layer of anodizable metal protects the portion of the layer of the superconductor material from the anodic oxidation; wherein the superconductor material is aluminium.

Another aspect provides the use of a titanium layer to protect an aluminium layer from anodic oxidation.

A still further aspect provides a semiconductor-superconductor hybrid device, comprising: a semiconductor component; a superconductor component arranged over the semiconductor component; and an oxide layer arranged over the semiconductor component and the superconductor component; wherein the superconductor component comprises aluminium; and wherein the oxide layer consists of aluminium oxide.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Nor is the claimed subject matter limited to implementations that solve any or all of the disadvantages noted herein.

### BRIEF DESCRIPTION OF THE DRAWINGS

To assist understanding of embodiments of the present disclosure and to show how such embodiments may be put into effect, reference is made, by way of example only, to the accompanying drawings in which:

FIG. 1 is a flow diagram outlining a first example method of patterning a layer of superconductor material;

FIGS. 2a to 2d are cross-sections illustrating workpieces obtained at the various stages of the method of FIG. 1;

FIG. 3 is a diagram illustrating anodic oxidation of aluminium;

FIG. 4a is a plot of critical magnetic field against temperature for aluminium layers treated by anodic oxidation compared to an as grown, AG, aluminium layer, with the magneticfield being applied parallel to the plane of the aluminium layers;

FIG. 4b is a plot of critical magnetic field against temperature for aluminium layers treated by anodic oxidation compared to an AG aluminium layer, with the magnetic field being applied perpendicular to the plane of the aluminium layers;

FIG. 5 is a plot comparing charge mobility in the semiconductor component of a semiconductor-superconductor hybrid device fabricated by using an etching process was used to pattern the superconductor component with charge mobility in the semiconductor component of a semiconductor-superconductor hybrid device fabricated in accordance with the method of the present disclosure;

FIG. 6 is a plot showing resistance as a function of applied magnetic field strength for aluminium layers which were protected by titanium layers of different thicknesses;

FIG. 7 is a flow diagram outlining a second example method of patterning a layer of superconductor material; and

FIGS. 8a to 8d are cross-sections illustrating workpieces obtained at various stages of the method of FIG. 7.

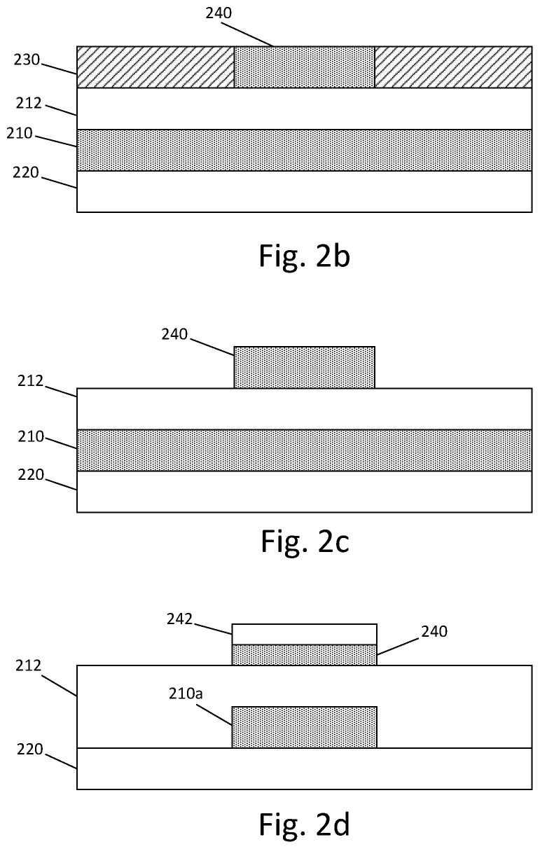

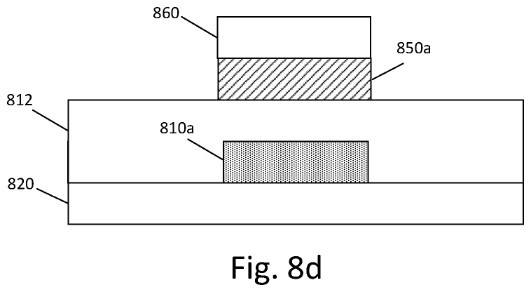

As will be appreciated, FIGS. 2 and 8 are schematic and not to scale. Relative proportions of components shown in these figures may be exaggerated for ease of representation.

### DETAILED DESCRIPTION

As used herein, the verb ‘to comprise’ is used as shorthand for ‘to include or to consist of’. In other words, although the verb ‘to comprise’ is intended to be an open term, the replacement of this term with the closed term ‘to consist of’ is explicitly contemplated, particularly where used in connection with chemical compositions.

Directional terms such as “top”, “bottom”, “left”, “right”, “above”, “below”, “horizontal” and “vertical” are used herein for convenience of description and refer to the orientation shown in FIGS. 2 and 8. For the avoidance of any doubt, this terminology is not intended to limit the orientation of the device in an external frame of reference.

The abbreviation “2DEG” refers to a 2-dimensional electron gas. The abbreviation “AG” means “as grown”.

As used herein, the term “superconductor” refers to a material which becomes superconductive when cooled to a temperature below a critical temperature, T_{c}, of the material. The use of this term is not intended to limit the temperature of the device, or the temperature at which any method step is performed.

A “nanowire” is an elongate member having a nano-scale width, and a length-to-width ratio of at least 100, or at least 500, or at least 1000. In an additional example, a nanowire may be an elongate member having a nano-scale width, and a length-to-width ratio of at least 10. A typical example of a nanowire has a width in the range 10 to 500 nm, optionally 50 to 100 nm or 75 to 125 nm. Lengths are typically of the order of micrometres, e.g. at least 1 μm, or at least 10 μm.

The term “coupling” in the context of the present disclosure refers to the hybridisation of energy levels.

A “semiconductor-superconductor hybrid structure” comprises a semiconductor component and a superconductor component which may become coupled to one another under certain operating conditions. In particular, this term refers to a structure capable of showing topological behaviour such as Majorana zero modes, or other excitations useful for quantum computing applications. The operating conditions generally comprise cooling the structure to a temperature below the Tc of the superconductor component, applying a magnetic field to the structure, and applying electrostatic gating to the structure. Generally, at least part of the semiconductor component is in intimate contact with the superconductor component, for example the superconductor component may be epitaxially grown on the semiconductor component. Certain device structures having one or more further components between the semiconductor component and superconductor component have however been proposed.

In order to allow useful excitations to be induced in a semiconductor-superconductor hybrid device, a good quality interface between the semiconductor component and the superconductor component is needed.

Semiconductor-superconductor hybrid devices which use aluminium as the superconductor component have been investigated. Aluminium has various favourable properties, including good lattice matching with, and good coupling to, various semiconductor materials. In particular, aluminium has been reported to be very effective for inducing a proximity effect in indium arsenide (see, e.g. Krogstrup et al., Nature Materials 14, 400-406 (2015); Chang et al, Nature Nanotechnology 10, 232-236 (2015); Shabani et al, Phys. Rev. B 93, 155402 (2016); Kjaergaard et al, Nat Commun 7, 12841 (2016); Krizek et al, Phys. Rev. Mat 2, 093401 (2018); and Vaitiekenas et al, Phys. Rev. Lett 121, 147701 (2018)).

Previous approaches to fabricating semiconductor-superconductor hybrid devices have involved forming a layer of superconductor material on a semiconductor component, and then chemically etching the superconductor material to form the superconductor component. When forming the layer of superconductor material, a very good quality interface between the superconductor and semiconductor is achievable. However, the chemical etch has limited resolution, and may degrade the semiconductor or cause damage to the interface. This results in poor reproducibility. It would be desirable to allow patterning of aluminium without the use of chemical etching.

It would also be desirable to provide a semiconductor-superconductor hybrid device with improved properties. Despite aluminium's various favourable properties, it has a small superconducting gap (see, C. Kittel (2004) Introduction to Solid State Physics. Wiley. ISBN: 9780471415268). A larger superconducting gap may be desirable, because this may allow the size of the topological gap in the hybrid device to be increased. The topological gap is an energy gap between a lower energy band and an upper energy band, with the useful Majorana zero modes residing in the lower band. Increasing the size of the topological gap may, for example, improve the lifetime of Majorana zero modes induced in the device.

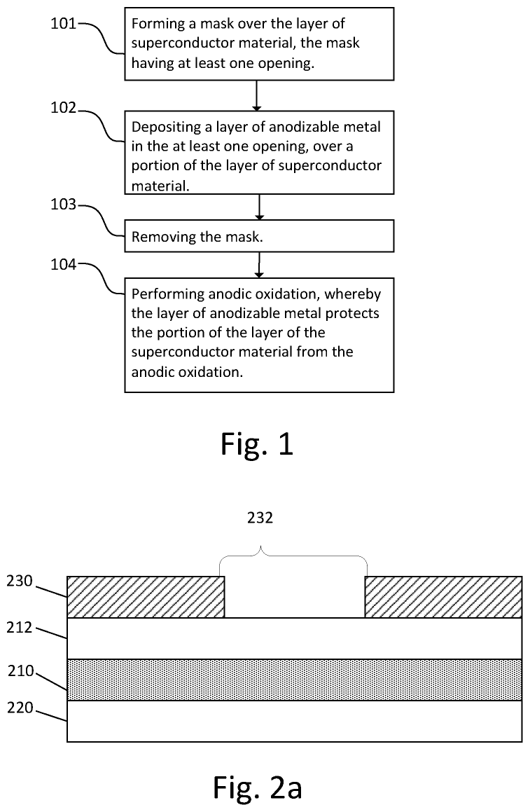

An example method of patterning a layer of superconductor material will now be described with reference to FIGS. 1 and 2 simultaneously. FIG. 1 is a flow chart outlining the method; and FIG. 2 is a series of schematic diagrams illustrating workpieces obtained at various stages of the method.

Although the present method is described with reference to the fabrication of a semiconductor-superconductor hybrid device, the method is broadly applicable to the patterning of aluminium components.

The superconductor layer 210 comprises aluminium. Aluminium oxidizes when exposed to oxygen. For example, aluminium naturally oxidizes to a depth of about 3 nm on exposure to air. The superconductor layer 210 is therefore typically covered by an oxide layer 212. In implementations where the superconductor layer is not exposed to oxygen, oxide layer 212 may be absent.

The superconductor layer 210 may be formed by any appropriate process, for example, by a deposition process. Examples of deposition processes include sputtering, evaporation, and chemical vapour deposition processes such as atomic layer deposition and metal-organic vapour deposition.

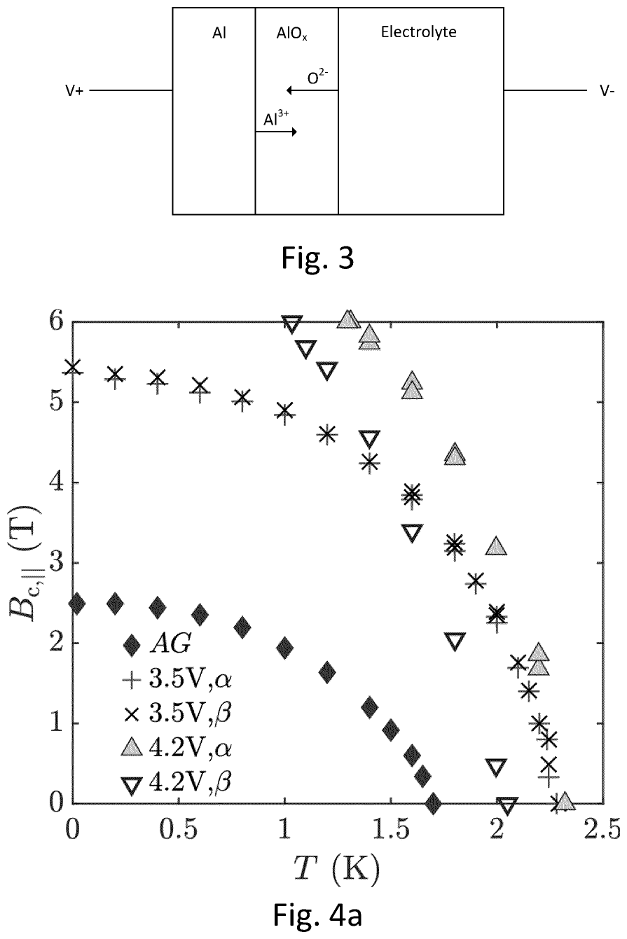

After forming the superconductor layer 210, the layer may be thinned by an anodic oxidation process. Anodic oxidation will be described in more detail below with reference to FIG. 3. The inventors have found that partial oxidation of aluminium may increase the critical temperature and critical magnetic field of the resultant aluminium layer, as demonstrated in Examples 1 and 3, below.

The depth to which the anodic oxidation oxidises the superconductor layer 210 may be controlled by selecting the applied voltage. In a thinning process, the voltage is selected such that only a partial thickness of the superconductor layer will oxidise, with the remainder of the layer remaining as native superconductor.

After the thinning process, the superconductor layer 210 may in some implementations have a thickness of 1 nm or less. and may be as thin as two monolayers.

The thickness of the aluminium layer which may be patterned using the method described below is not particularly limited. The thinning step may be completely omitted in some implementations. In other words, the patterning method may be applied to an as-grown aluminium layer.

The superconductor layer 210 may be arranged on a semiconductor component 220. The semiconductor component may be in the form of a nanowire, e.g. a selective-area-grown or vapour-liquid-solid grown nanowire. The semiconductor component may be configured to support a 2-dimensional electron gas, 2DEG.

The nature of the semiconductor material is not particularly limited. Examples of useful semiconductors include Ill-V semiconductors, in particular those of Formula 1:

InAsₓSb₁₋ₓ (Formula 1)

where x is in the range 0 to 1. In other words, semiconductor component 220 may comprise indium antimonide (x=0), indium arsenide (x=1), or a ternary mixture comprising 50% indium on a molar basis and variable proportions of arsenic and antimony (0<x<1).

Indium arsenide, InAs, has been found to have good handling properties, and provides devices with good performance. Indium antimonide, InSb, may provide further improvements to device performance but may have less favourable handling properties. The ternary mixtures have intermediate properties between those of the binary compounds InAs and InSb. Improvements in device performance compared to InAs may be observed when x is in the range 0 to 0.7, or 0.01 to 0.7. Values of x in the range 0.35 to 0.45 may provide a particularly good balance of device performance and handling properties.

Indium arsenide may be preferred for some implementations. As components of hybrid devices may be fabricated by epitaxial growth processes, good lattice matching between component materials may be desirable. Indium arsenide has good compatibility with aluminium.

The superconductor layer 210 and semiconductor component 220 may be arranged on a substrate. The substrate may be any structure on which the device is to be constructed. The substrate typically comprises a wafer of semiconductor material. A wafer is a piece of single crystalline material. One example wafer material is indium phosphide, which is a high band-gap semiconductor. Other examples of wafer materials include gallium arsenide, gallium antimonide, and silicon. The substrate may be a more elaborate workpiece, further comprising additional structures arranged on or over the wafer. The substrate may include layers of two or more materials. The substrate may for example include a dielectric mask for a selective area growth process, arranged on a substrate.

At block 101, a mask 230 is formed over the layer of superconductor material. The mask has at least one opening 232. An illustrative workpiece obtained at this stage is illustrated in FIG. 2a.

The nature of the mask is not particularly limited, provided that the mask 230 is capable of controlling the deposition of an anodizable metal at a subsequent stage of the process.

The position of the opening 232 in the mask 230 will determine the position of the superconductor component in the finished device.

Any appropriate mask may be used. One illustrative example of a technique for forming a mask is electron beam lithography. This involves applying a resist to the substrate, selectively exposing areas of the resist to an electron beam, and then developing the resist to form the mask. Examples of resists useful for electron beam lithography include hydrogen silsesquioxane and poly(acrylates) such as poly(methyl methacrylic acid).

Referring now to block 102 and FIG. 2b, a layer of anodizable metal 240 is deposited in the openings defined in the mask 230. The layer of anodizable metal 240 acts as mask for controlling anodizing oxidation of the superconductor layer 210 in a later step of the method.

Examples of anodizable metals include titanium, aluminium, niobium and tantalum. In particular, the anodizable metal may be titanium or aluminium, with titanium being particularly preferred. In addition to being anodizable, titanium has good wetting properties and can be selectively removed by chemical processes.

The process used to form the layer of anodizable metal may be selected as appropriate depending on the metal chosen.

The thickness of the layer of anodizable material is not particularly limited and may be selected as appropriate. The layer may have a thickness in the range 5 to 8 nm, with thicknesses in this range providing good protection to the superconductor layer and being relatively easy to remove by lift-off. A thickness of at least about 5 nm may be preferred. Thinner layers may be used but are more difficult to remove by lift-off.

At block 103, mask 230 is removed. The mask 230 may be removed using any appropriate process, and in particular by lift-off. The layer of anodizable metal 240 remains on the workpiece at this stage of the process, as illustrated in FIG. 2c.

At block 104, anodic oxidation is performed, yielding the workpiece shown in FIG. 2d.

The conditions, e.g. voltage, used for the anodic oxidation may be selected such that the full thickness of the superconductor layer 210 is oxidized, with the exception of the portion of the superconductor layer 210a which is under the layer of anodizable metal 240. The anodic oxidation may therefore allow patterning of the superconductor layer 210 without requiring a chemical etch of the superconductor layer 210. This may avoid damage to the semiconductor component 220 and/or the interface between the semiconductor component and the superconductor component.

A lateral resolution of below 50 nm may be achievable using this technique. In contrast, chemical etching using a mask has limited lateral resolution because the etchant may under-run the mask, resulting in over-etching.

This operation may also partially or fully oxidize the anodizable metal 240, forming oxide layer 242.

The method may further comprise, after performing the anodic oxidation, selectively removing the layer of anodizable metal 240. Oxide layer 242 is removed in such implementations. This inclusion of this step may be preferred in implementations where titanium is used as the anodizable metal. Removing the anodizable metal may be desirable if the anodizable metal 240 and/or its oxide 242 would interfere with the operation of the device.

By selective removal is meant removing the layer of anodizable metal 240 and its oxide 242 without removing the aluminium oxide 212.

One example process which may be used to achieve selective removal is fluorine dry etching. This process is particularly useful where titanium is used as the anodizable metal.

In implementations where selective removal of the layer of anodizable metal 240 is performed, an optional cleaning step may be performed after the removal. The cleaning step may comprise a wet hydrogen fluoride dip. The selective removal may cause some damage the surface of the aluminium oxide layer, and the cleaning step may improve the quality of the surface.

Various modifications to the described method are possible.

In one variant, the steps of forming the mask as in block 102 and subsequently removing the mask at block 103 are omitted. Instead, a layer of anodizable metal is deposited over the workpiece, and then etched to pattern the layer of anodizable metal. One example implementation of this variant method uses niobium as the anodizable metal. The niobium may be deposited over the layer of superconductor material by sputtering. The niobium may then be patterned by a fluorine-based dry etch. The anodic oxidation step then proceeds as described above.

In another variant, a layer of a suitable dielectric material, such as SiOx, may be used instead of an anodizable metal.

An anodic oxidation process will now be described with reference to FIG. 3. Anodic oxidation is applicable both to the optional thinning of the superconductor layer which may be performed before block 101, and to the anodic oxidation performed at block 104.

In an anodic oxidation process, the superconductor layer is connected to an anode and placed in an electrolyte bath. A suitable cathode is also placed in the electrolyte bath. An oxidation reaction occurs at the interface between the aluminium and the electrolyte, forming aluminium oxide.

The depth of the oxidation process into the aluminium may be controlled by varying the applied voltage. It has been observed that the depth of oxidation increases approximately linearly with applied voltage. The voltage may be selected as appropriate. Illustrative voltages are in the range 2 to 6 V.

When the layer of anodizable metal 240 is present, a voltage that completely oxidizes the unprotected aluminium may not oxidize, or may only partly oxidize, the aluminium protected by the anodizable metal.

The electrolyte solution used in the anodic oxidation may comprise a tartaric acid solution. The electrolyte solution may be adjusted to a pH in the range 5 to 6, e.g., about 5.5 using an appropriate base, such as ammonium hydroxide. This electrolyte solution was used in the practice of the examples reported herein. Any other appropriate electrolyte may be used.

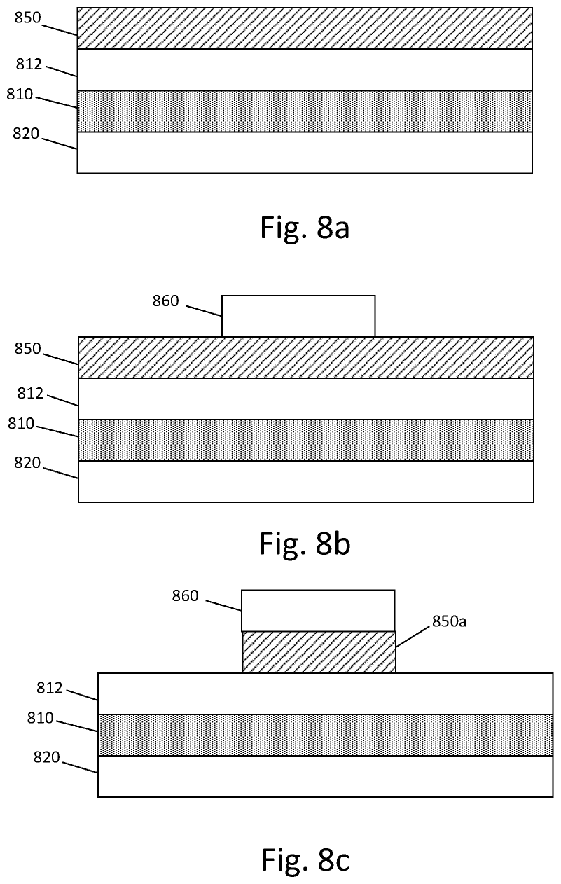

A further method of patterning a layer of superconductor material will now be described with reference to FIG. 7.

The superconductor material is aluminium. The layer of superconductor material may be arranged on a semiconductor component. The layer of superconductor material and the semiconductor component may be arranged on a substrate. The superconductor material, semiconductor material and/or substrate may each individually be as described above with reference to FIG. 2.

At block 701, the layer of superconductor material is thinned by anodic oxidation. This operation is optional, and may be omitted in some implementations. The thinning may be performed as described with reference to FIG. 3. Thinning the layer of superconductor material may increase the critical field and/or critical temperature of the superconductor material.

After the thinning, the layer of superconductor material may have a thickness in the range 2 to 10 nm, e.g. 2 to 5 nm, preferably about 2 nm. Although thicknesses below 2 nm may be used, very thin layers may display unusual behaviour. Further reductions in thickness may cause the critical field and/or critical temperature to begin to reduce.

At block 702, a layer of dielectric material is deposited over the layer of superconductor material. The deposition is typically a global deposition. In other words, the entire surface of the layer of superconductor material is coated with dielectric material.

An example workpiece which may be obtained at this stage is illustrated in FIG. 8a. FIG. 8a shows a layer of dielectric material 850 arranged on aluminium oxide layer 812 at the surface of aluminium layer 810, the aluminium layer 810 being arranged on a semiconductor component 820.

The dielectric material may be selected from a silicon oxide (SiOx) and a silicon nitride. These are examples of materials which may be selectively etched in the presence of aluminium oxide.

The dielectric material may be deposited using a technique selected from atomic layer deposition, sputtering, and chemical vapour deposition processes such as plasma enhanced chemical vapour deposition, PECVD.

Atomic layer deposition and sputtering may be performed at relatively low temperatures, and may be preferred in implementations where a semiconductor component comprising a material of Formula 1 is present.

Atomic layer deposition is particularly preferred because the layer of dielectric material may be deposited a monolayer at a time, thereby allowing for precise control over the thickness of the dielectric layer.

At block 703, a first mask is formed on the dielectric layer and over a first portion of the layer of superconductor material. The mask is used in a subsequent operation to control a selective etch of the dielectric layer.

The mask may be formed by electron beam lithography, for example as described above with reference to FIG. 1, block 101. A schematic illustration of a workpiece including a first mask 860 is shown in FIG. 8b.

At block 704, the dielectric layer is selectively etched through the first mask, to form a mask 850a of the dielectric material over the first portion of the layer of superconductor material. The mask of dielectric material is used in a subsequent step to control patterning of the layer of superconductor material by anodic oxidation. An example workpiece including mask 850a is shown in FIG. 8c.

The etch selectively removes portions of the dielectric layer which are not covered by the mask, while leaving the aluminium layer and its associated oxide intact.

The etching conditions may be selected as appropriate depending on the dielectric material chosen. In implementations where the dielectric material comprises silicon oxide or silicon nitride, the etch may be a fluoride-based reactive ion etch. Fluoride-based reactive ion etching selectively removes silicon oxide and silicon nitride without removing aluminium oxide. Fluoride-based reactive ion etching is a dry etching process, and has good resolution.

At block 705, anodic oxidation is performed, whereby the dielectric mask protects the first portion 810a of the layer of superconductor material from being fully oxidized by the anodic oxidation. This patterns the layer of superconductor material. An example workpiece obtainable at this stage is shown in FIG. 8d.

The anodic oxidation may be as described with reference to FIG. 3.

The thickness of the dielectric layer and the conditions used for the anodic oxidation may be selected such that the anodic oxidation partially oxidises the first portion of the layer of superconductor material through the dielectric mask. Patterning and thinning of the layer of superconducting material may therefore be performed in a single step. This is particularly useful in implementations where operation 701 is omitted.

At block 706, the dielectric mask is removed, for example by a selective etch. This operation is optional, and may be omitted.

Using a selective etch, as opposed to a lift-off process, to form the mask for controlling the anodic oxidation of the superconductor material may allow for the fabrication of devices having superconductor components with smaller lateral dimensions. Superconductor components having lateral dimensions of the order of 10 nm may be readily fabricated using this technique. In contrast, when a diffusive dielectric deposition is implemented, it can be difficult to fabricate components having lateral dimensions of less than about 1 μm when using lift-off to define the mask for controlling the anodic oxidation.

It will be appreciated that the above embodiments have been described by way of example only.

More generally, according to a first aspect disclosed herein, there is provided a method of patterning a layer of superconductor material, which method comprises: forming a mask over the layer of superconductor material, the mask having at least one opening; depositing a layer of anodizable metal in the at least one opening, over a portion of the layer of superconductor material; removing the mask; and performing anodic oxidation, whereby the layer of anodizable metal protects the portion of the layer of the superconductor material from the anodic oxidation; wherein the superconductor material is aluminium. This allows for the patterning of an aluminium layer using a selective anodic oxidation, without the use of a chemical etch. This may allow for improvements in resolution, and/or may avoid damage to further components or interfaces between components which may be present during the patterning.

The anodizable metal may be titanium. Titanium has good wettability. Titanium and its oxide may be selectively removed in the presence of aluminium and aluminium oxide, which may be advantageous in some implementations. The presence of titanium and/or titanium oxide can have a negative impact on the operation of certain devices.

The layer of anodizable metal may have a thickness of at least 5 nm, optionally at least 6 nm. Layers having these thicknesses have been found to be particularly effective for protecting the aluminium layer, with no or very little oxidation of the aluminium layer occurring through the layer of anodizable metal.

The thickness of the anodizable metal may be selected such that the portion of the layer of the superconductor material is partially oxidized by the anodic oxidation. This may allow thinning of the layer of the superconductor material without an additional process step. Thinning may improve the critical field and/or critical temperature of the superconductor material.

In implementations where the anodizable metal is titanium, the method may further comprise, after performing the anodic oxidation, selectively removing the layer of anodizable metal. For example, the layer of anodizable metal may be removed by a fluorine dry etch.

This process is effective for selectively removing titanium and titanium oxide in the presence of aluminium oxide.

The method may further comprise, after selectively removing the layer of protective metal, cleaning the resulting workpiece by a wet hydrogen fluoride dip. This may remove damaged portions of aluminium oxide. Improving the surface of the device may be useful for, e.g., facilitating the subsequent fabrication of additional components such as gate electrodes.

The layer of superconductor material may be arranged on a semiconductor component. Anodic oxidation may cause less damage to semiconductors than chemical etching. The method provided herein is particularly applicable to the fabrication of devices comprising a combination of semiconductor and superconductor components.

The semiconductor component may comprise a material of Formula 1:

InAsₓSb₁₋ₓ (Formula 1)

where x is in the range 0 to 1. For example, the semiconductor component comprises indium arsenide. Indium arsenide has been reported to couple particularly well to aluminium.

Tartaric acid may be used as an oxidant for the anodic oxidation. This oxidant was used in the practice of the examples reported herein. Alternative oxidants may be used.

The method may further comprise, before forming the mask, thinning the layer of superconductor material by partial oxidation. Thinning the layer of superconductor material may comprise performing partial anodic oxidation of the layer of superconductor material. Thinning the layer of superconductor material may improve its critical field and/or critical temperature. After the thinning, the layer of superconductor material may, for example, have a thickness of less than or equal to 1 nm.

The mask may be formed by electron beam lithography. The layer of anodizable metal may be formed by evaporation. Removing the mask may comprise a lift-off process.

Another aspect provides the use of a titanium layer to protect an aluminium layer from anodic oxidation. For example, the titanium layer may be used as a mask in a process of patterning the aluminium layer by anodic oxidation. This allows for the patterning of an aluminium layer without the use of a chemical etch. This may allow for improvements in resolution, and/or may avoid damage to further components or interfaces between components which may be present during the patterning.

The titanium layer has a thickness of at least 5 nm, optionally at least 6 nm. Layers having these thicknesses may be particularly effective for protecting the aluminium layer.

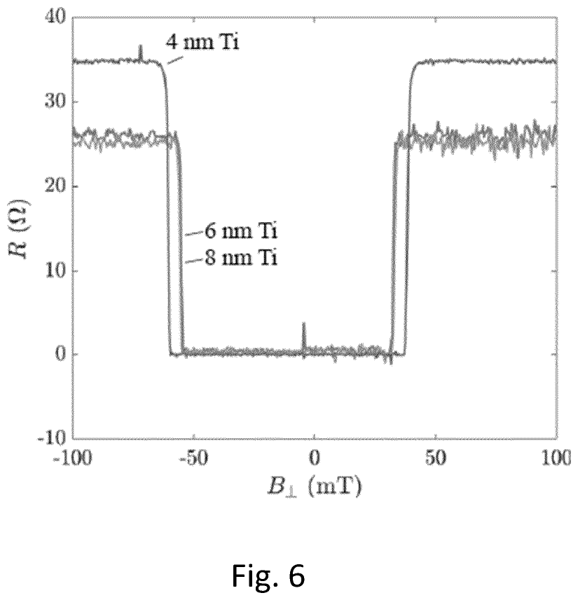

The use may be in the context of a method of fabricating a semiconductor-superconductor hybrid device. Chemical etching can damage the surface of the semiconductor, resulting in scattering effects which negatively affects device performance. It is thus particularly desirable to avoid the use of chemical etching when fabricating such devices. FIG. 5 demonstrates an improvement achievable when using anodic oxidation rather than a chemical etch.

It will be appreciated that any of the features described with reference to the method aspect are also applicable to the use aspect.

Another aspect provides a semiconductor-superconductor hybrid device obtainable by the method of the present disclosure.

For example, there is provided a semiconductor-superconductor hybrid device, comprising: a semiconductor component; a superconductor component arranged over the semiconductor component; and an oxide layer arranged over the semiconductor component and the superconductor component; wherein the superconductor component comprises aluminium; and wherein the oxide layer consists of aluminium oxide. Since the device may be fabricated without a chemical etch, performance may be improved.

The superconductor component may have a thickness of less than or equal to 1 nm. Layers having such thicknesses may have higher critical field and/or critical temperature, indicative of improved superconductive gap.

The semiconductor-superconductor hybrid device may further comprise a layer of titanium and/or titanium oxide arranged on the oxide layer and over the superconductor component.

It will be appreciated that features described with reference to the method or use aspects are also applicable to the device aspect.

Another aspect provides a method of patterning a layer of superconductor material having a thickness, which method comprises:
forming a mask over the layer of superconductor material, wherein the mask covers a first portion of the layer of superconductor material and exposes a second portion of the layer of superconductor material; and
performing anodic oxidation,
wherein the mask protects the first portion of the layer of superconductor material from being fully oxidized through by the anodic oxidation; and
wherein the second portion of the layer of superconductor material is fully oxidized by the anodic oxidation. The method allows for the patterning of an aluminium layer using a selective anodic oxidation, without the use of a chemical etch. This may allow for improvements in resolution, and/or may avoid damage to further components or interfaces between components which may be present during the patterning.

By “fully oxidized” is meant “oxidized to completion”. In other words, when fully oxidized, the full thickness of the superconductor layer is oxidized.

Protecting the layer of superconductor material may comprise preventing any oxidation of the superconductor material under the mask; or may comprise limiting the extent of the oxidation such that only a partial thickness of the layer of superconductor material is oxidized.

The mask may comprise an anodizable metal.

Alternatively, the mask may comprise a dielectric material such as silicon oxide (SiOx) or silicon nitride (SiNₓ).

The superconductor material may be aluminium.

The mask may be formed by a lift-off process. In such implementations, the method may be as described with reference to the first aspect.

Alternatively, the mask may be formed by forming a layer of mask material; and patterning the layer of mask material. For example, the mask material may be niobium. The layer of niobium may be formed by sputtering. The layer of niobium may be patterned using a fluorine-based dry etch.

Features described with reference to the first aspect are also applicable to this aspect. In particular, the method may further comprise a thinning step, as described with reference to the first aspect.

The mask material may be a dielectric material selected from a silicon oxide and a silicon nitride.

The layer of mask material may be formed by atomic layer deposition. Atomic layer deposition may allow precise control over the thickness of the mask material. Other examples of processes for forming the layer of mask material include sputtering and plasma enhanced chemical vapour deposition, PECVD.

The layer of mask material may be patterned using a fluoride-based reactive ion etch. Fluoride-based reactive ion etching allows for the selective etching of silicon oxide or silicon nitride in the presence of aluminium oxide.

The layer of mask material may have a thickness selected such that the first portion of the layer of superconductor material is thinned by the anodic oxidation. In such implementations, thinning and patterning may be performed as a single step.

Still another aspect provides a method of improving the superconductive properties of an aluminium layer, which method comprises thinning the aluminium layer by anodic oxidation. Improving the superconductive properties may comprise increasing one or both of the critical temperature and/or critical field of the aluminium layer compared to an as-grown aluminium layer.

The electrolyte used in the anodic oxidation may comprise a tartaric acid solution. The electrolyte may have a pH in the range 5 to 6, optionally 5.5±0.1. The tartaric acid solution may further comprise a pH adjuster, for example ammonium hydroxide.

The thickness of the aluminium layer after the anodic oxidation may be less than or equal to 1 nm.

The anodic oxidation may comprise applying a voltage in the range 2 to 12 V, optionally 3 to 6 V. The thickness of the aluminium layer after the thinning may be controlled by varying the applied voltage.

### EXAMPLES

### Example 1—Effects of Thinning by Anodic Oxidation on Superconductor Properties

To demonstrate the effects of thinning on the performance of an aluminium superconductor layer, the critical magnetic field as a function of temperature was investigated for some example aluminium thin films.

Anodic oxidation was performed at various different voltages using tartaric acid as the electrolyte. A control, as grown, film which was not treated by anodic oxidation was also investigated. Two films were treated with a voltage of 3.5 V, and two films were treated with a voltage of 4.2 V.

The effects of magnetic fields applied parallel and perpendicular to the plane of the aluminium layer were investigated.

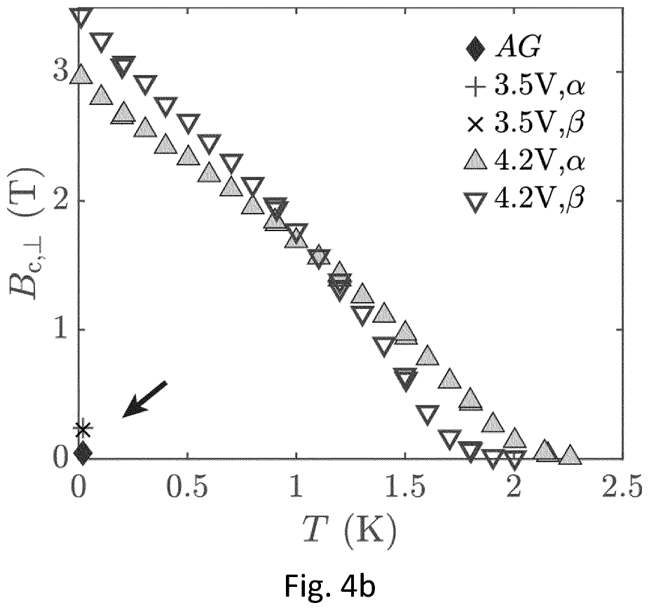

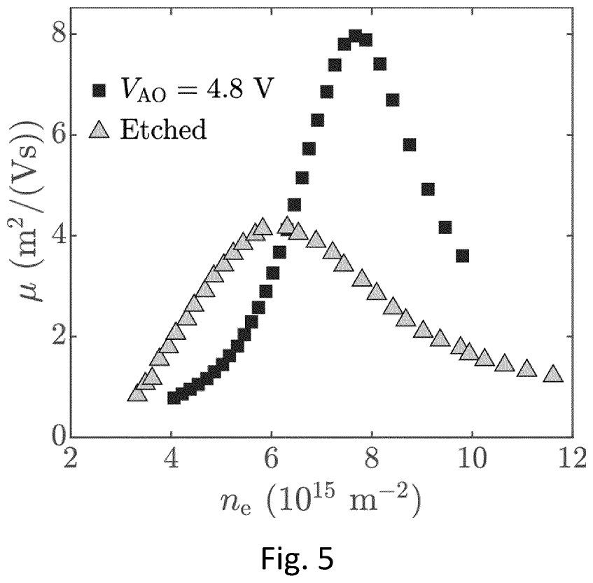

FIG. 4a illustrates the effects of parallel field. Results for the control film are labelled “AG”. As may be seen, applying anodic oxidation increased the parallel critical field (i.e., the upper limit on magnetic field strength which can be tolerated before superconductivity is lost) at a given temperature. Critical temperature, corresponding to the temperature at which the critical field drops to zero, was also increased.

FIG. 4b illustrates the effects of a perpendicular field. In FIG. 4b, the base temperature critical perpendicular field for the as-grown, AG, film and 3.5 V anodized film are highlighted by an arrow.

A dramatic increase in critical perpendicular field was observed for the aluminium layer anodized at 4.2 V.

The results demonstrate that performance of the aluminium superconductor may be improved by applying anodic oxidation.

### Example 2—Effects of Different Patterning Processes on Semiconductor Performance

A first, comparative, semiconductor-superconductor hybrid device was fabricated, using a chemical etch to pattern the superconductor component.

A second semiconductor-superconductor hybrid device was fabricated using a method according to the present disclosure. The voltage used during the anodic oxidation step was 4.8 V.

Charge mobility in the two devices was investigated. The results are shown in FIG. 5.

As may be seen, the semiconductor component of the comparative device had lower charge mobility. This may be attributed to degradation caused by the wet etch. The results illustrate that patterning using anodic oxidation may avoid degradation of the semiconductor.

### Example 3—Anodic Oxidation of Aluminium Layer Through a Titanium Oxide Mask

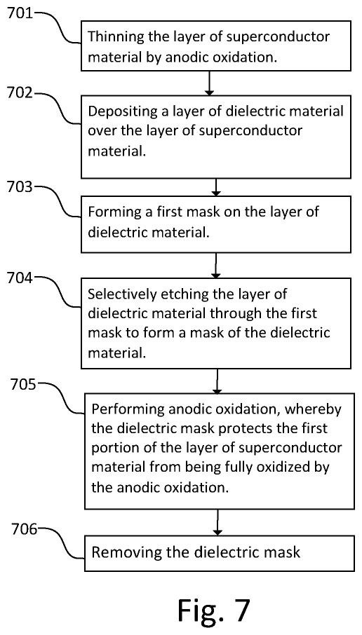

The critical field of aluminium layers protected by titanium layers having various thicknesses was investigated, with the results being shown in FIG. 6. The layers were fabricated on the same chip, and an anodic oxidation using a tartaric acid oxidant and a 4.8 V applied voltage was performed.

The results demonstrate that an aluminium layer protected by a 4 nm thick titanium layer showed different behaviour to the aluminium layers protected by 6 nm and 8 nm thick layers. It is believed that the aluminium layer was partly oxidized through the 4 nm thick titanium layer under the conditions tested. This provided an improvement in superconductor properties, illustrated by an increase in critical field.

This illustrates that a separate thinning step may not be necessary for achieving an improvement in superconductor properties, and that thinning alternatively be achieved by selecting the thickness of the anodizable metal and the conditions of the anodic oxidation.

Other variants or use cases of the disclosed techniques may become apparent to the person skilled in the art once given the disclosure herein. The scope of the disclosure is not limited by the described embodiments but only by the accompanying claims.

1-15. (canceled)

16. A method of patterning a layer of superconductor material, comprising:
forming a mask over the layer of superconductor material, the mask having at least one opening;
depositing a layer of an anodizable metal in the at least one opening, over a portion of the layer of superconductor material;
removing the mask; and
performing anodic oxidation, whereby the layer of anodizable metal protects the portion of the layer of the superconductor material from the anodic oxidation;
wherein the superconductor material is aluminium.

17. The method according to claim 16, wherein the anodizable metal is titanium.

18. The method according to claim 17, wherein the layer of the anodizable metal has a thickness of at least 5 nm.

19. The method according to claim 17, further comprising, after performing the anodic oxidation, selectively removing the layer of the anodizable metal.

20. The method according to claim 19, wherein the layer of the anodizable metal is removed by a fluorine dry etch.

21. The method according to claim 19, further comprising after selectively removing the layer of protective metal, cleaning a resulting workpiece by a wet hydrogen fluoride dip.

22. The method according to claim 16, wherein the layer of superconductor material is arranged on a semiconductor component.

23. The method according to claim 22, wherein the semiconductor component comprises a material of formula 1:
InAsₓSb₁₋ₓ (Formula 1)
wherein x is in a range 0 to 1.

24. The method according to claim 23, wherein the semiconductor component comprises indium arsenide.

25. The method according to claim 16, wherein tartaric acid is used as an oxidant for the anodic oxidation.

26. The method according to claim 16, further comprising, before forming the mask, thinning the layer of superconductor material by partial oxidation, and wherein, after the thinning, the layer of superconductor material has a thickness of less than or equal to 1 nm.

27. The method according to claim 26, wherein thinning the layer of superconductor material comprises performing partial anodic oxidation of the layer of superconductor material.

28. The method according to claim 16, wherein:
the mask is formed by electron beam lithography, and/or
the layer of the anodizable metal is formed by evaporation, and/or
removing the mask comprises a lift-off process.

29. A method, comprising:
applying a titanium layer to an aluminum layer to define an exposed portion of the aluminum layer and an unexposed portion of the aluminum layer; and
performing anodic oxidation of the exposed portion of the aluminum layer, wherein the titanium layer protects the unexposed portion of the aluminum layer from the anodic oxidation.

30. The method of claim 29, wherein the titanium layer has a thickness of at least 5 nm.

31. The method of claim 29, further comprising fabricating a semiconductor-superconductor hybrid device on the aluminum layer.

32. A semiconductor-superconductor hybrid device, comprising a component made by the method of claim 16.

33. A semiconductor-superconductor hybrid device, comprising:
a semiconductor component;
a superconductor component arranged over the semiconductor component; and
an oxide layer arranged over the semiconductor component and the superconductor component;
wherein the superconductor component comprises aluminium; and
wherein the oxide layer consists of aluminium oxide.

34. The semiconductor-superconductor hybrid device according to claim 33, wherein the superconductor component has a thickness of less than or equal to 1 nm.

35. The semiconductor-superconductor hybrid device according to claim 33, further comprising a layer of titanium and/or titanium oxide arranged on the oxide layer and over the superconductor component.
